(19) United States
(12) Patent Application Publication
(10) Pub. No.: US 2026/0240058 A1
(43) Pub. Date: Aug. 13, 2026

(54) Method of Fine Pitch Hybrid Bonding with Dissimilar CTE Wafers and Resulting Structures

(71) Applicant: Apple Inc., Cupertino, CA (US)

(72) Inventors: Saijin Liu, San Jose, CA (US); Fang Ou, San Jose, CA (US); Tongbi T. Jiang, Santa Clara, CA (US)

(21) Appl. No.: 19/637,619

(22) Filed: Apr. 2, 2026

Related U.S. Application Data
(62) Division of application No. 17/654,637, filed on Mar. 14, 2022.
(60) Provisional application No. 63/175,159, filed on Apr. 15, 2021.

(51) Int. Cl. H10W 99/00; H10F 39/00; H10F 39/18; H10W 72/00; H10W 72/90; H10W 80/00; H10W 90/00

(52) U.S. Cl. CPC H10W 99/00; H10W 72/90; H10F 39/018; H10F 39/026; H10F 39/18; H10F 39/809; H10F 39/811; H10W 72/07338; H10W 80/102; H10W 80/312; H10W 80/327; H10W 90/00; H10W 90/792

(57) ABSTRACT

Hybrid bonded structures and methods of manufacture are described. In an embodiment, a hybrid bonded structure includes a first plurality of first conductive bonding regions of a first substrate stack bonded directly to a second plurality of second conductive bonding regions of a second substrate stack, and a first dielectric layer of the first substrate stack bonded to a second dielectric layer of the second substrate stack with an intermediate organic adhesive layer.

### RELATED APPLICATIONS

This application is a divisional of co-pending U.S. application Ser. No. 17/654,637 filed Mar. 14, 2022, which claims the benefit of priority of U.S. Provisional Application No. 63/175,159 filed Apr. 15, 2021, both of which are herein incorporated by reference.

### BACKGROUND

### Field

Embodiments described herein relate to hybrid bonding techniques, and more particularly to hybrid bonding of dissimilar wafers.

### Background Information

Hybrid bonding including metal-metal and oxide-oxide bonding has generally been adopted as a suitable technology for mass production of high-density input/output (I/O) chips with ultra-small pad pitches. A traditional hybrid bonding sequence includes three main operations including oxide-to-oxide initial bonding at room temperature, heating to close dishing gap, and then further heating to compress metal-to-metal bonds. After the hybrid bonding process there is a follow up wafer level process including chemical mechanical polishing (CMP), redistribution layer (RDL) formation and/or other device finishing operations depending upon the particular application. Traditional hybrid bonding techniques require bonding of wafers with the same coefficient of thermal expansion (CTE) to be effective.

### SUMMARY

Hybrid bonded structures and methods of manufacture are described in which substrates or substrate stacks with dissimilar CTEs and fine conductive bonding region (pad) pitch can be bonded. In particular, the hybrid bonding sequences in accordance with embodiments can include a non-conductive bonding operation at low temperature (e.g. room temperature) followed by thinning of one of the mismatched CTE substrate stacks, and a subsequent conductive bonding operation at elevated temperature to join opposing conductive bonding regions. The thinning process may be facilitated by bringing together an organic adhesive layer and dielectric layer in opposing substrate stacks during the non-conductive bonding operation to achieve a sufficient bonding surface energy that can withstand the thinning process. Additionally, the thinning process in accordance with embodiments is performed before subjecting the joined substrate stacks to an elevated temperature process in order to avoid excessive strains caused by thermal expansion differences.

### BRIEF DESCRIPTION OF THE DRAWINGS

FIG. 1 is a flow chart for a hybrid bonding method in accordance with an embodiment.

FIG. 2 is a flow chart for a method of preparing a substrate stack for non-conductive bonding in accordance with an embodiment.

FIGS. 3A-3G are schematic cross-sectional side view illustrations for a method of hybrid bonding in accordance with an embodiment.

### DETAILED DESCRIPTION

Embodiments describe hybrid bonded structures and methods of manufacture. In particular, embodiments describe resultant structures and methods of hybrid bonding that can be achieved with substrate stacks characterized by different coefficients of thermal expansion (CTE), and more specifically substrate stacks including bulk substrates (e.g. wafers) with different CTE. In a specific implementation, this can allow hybrid bonding of diode arrays onto a silicon substrate, where the diode arrays are grown on a substrate such as GaAs (5.7 ppm/° C.) or sapphire (5.0 ppm/° C.) with significantly different CTE than silicon (2.6 ppm/° C.), where differences can be 2.0 or higher, such as over 3.0, at room temperature and above. Additionally, hybrid bonding with dissimilar CTE stacks can be accomplished at large scales, including wafer-to-wafer scale or die-to-wafer scale with die sizes larger than 1 mm×1 mm, such as larger than 3 mm×3 mm.

A hybrid bonded structure in accordance with embodiments described herein may include a first substrate stack hybrid bonded with a second substrate stack, the first characterized by a first CTE and the second substrate stack characterized by a second CTE different from the first CTE. In an embodiment, the first substrate stack includes a first dielectric layer and a first plurality of first conductive bonding regions, the second substrate stack includes a second dielectric layer and a second plurality of second conductive bonding regions, the first plurality of first conductive bonding regions is bonded directly to the second plurality of second conductive bonding regions, and the first dielectric layer is bonded to the second dielectric layer with an intermediate organic adhesive layer. In accordance with embodiments, a bonding interface exists between the hybrid bonded first substrate stack and the second substate stack, with the bonding interface extending between (or defined by contact of) the first dielectric layer and the intermediate organic adhesive layer and between the first plurality of first conductive bonding regions and the second plurality of second conductive bonding regions.

The intermediate organic adhesive layer in accordance with embodiments may be applied to one of the first and second substrate stacks before bonding the two together, and at least partially cured on top of one of the first and second substrate stacks. The at least partial curing can adhere the organic adhesive layer to the underlying substrate stack, and allow additional processing such as CMP to form a planar bonding surface along with one of the first or second pluralities of conductive bonding regions. After application of the organic adhesive layer, and optional further processing the corresponding substrate stack can then be used for wafer-to-wafer bonding or optionally be diced for die-to-wafer bonding.

The corresponding substrate stack to which the substrate stack including the organic adhesive layer will be bonded can include a dielectric layer is a specific composition so that subsequent bonding can be performed at low temperature, such as room temperature, while achieving a bonding surface energy with the organic adhesive layer that will be sufficient for subsequent wafer thinning to remove the underlying bulk substrate (e.g. with dissimilar CTE). For example, SiCN dielectric layer can achieve a bonding surface energy greater than 1.7 J/m2 with many organic adhesive layers such as polybenzoxazole (PBO), polyimide, etc. Following wafer thinning, a high temperature anneal process can be performed to complete bonding of the aligned conductive bonding regions (e.g. metal-metal bonding).

In one aspect, it has been observed that when bonding wafers or substrate stacks (e.g. wafers or bulk substrates with additional layers thereon) with different CTE, that the bonding can be damaged during heating and cooling processes due to strain between the wafers (or bulk substrates). For example, if a bonding temperature is 200° C. above room temperature stresses can cause delamination or damage in the substrate stacks, even if the hybrid bonding is die to wafer, with die size much smaller than wafer size.

In accordance with embodiments, hybrid bonding sequences are described which can allow for hybrid bonding between wafer or substrate stacks that have significantly different CTEs, such as 2.0 or higher, or even 3.0 or higher. In an embodiment, the hybrid bonded substrate sacks each have a maximum lateral dimension of at least 1 mm×1 mm, or more particularly at least 3 mm×3 mm, and as large as full wafer size. Embodiments may also include hybrid bonding of differently sized wafers, such as 4-6 inch wafers onto 12 inch or 300 mm wafers. In exemplary embodiments, the resulting structure can include micro diode arrays (e.g. sensing diodes or light emitting diodes) that are bonded directly to silicon driver dies. The hybrid bonded structures can then be integrated into a variety of applications, such as display devices, image sensor devices, etc.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, and “on” as used herein may refer to a relative position of one layer with respect to other layers. One layer “over” or “on” another layer or bonded “to” or in “contact” with another layer may be directly in contact with the other layer or may have one or more intervening layers. One layer “between” layers may be directly in contact with the layers or may have one or more intervening layers.

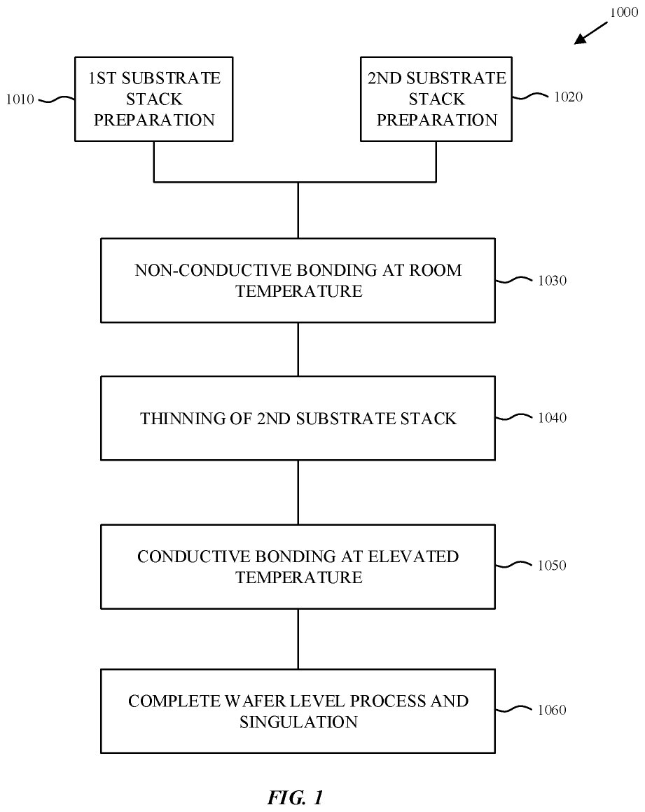

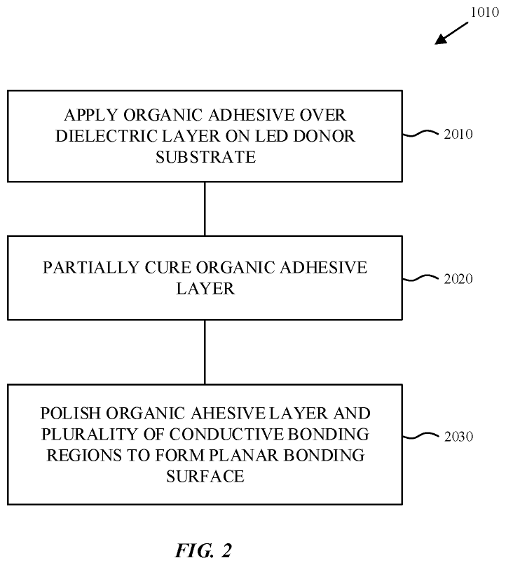

Referring now to FIGS. 1-2, FIG. 1 a flow chart is provided for a hybrid bonding method in accordance with an embodiment, and FIG. 2 is a flow chart for a method of preparing a substrate stack for non-conductive bonding in accordance with an embodiment.

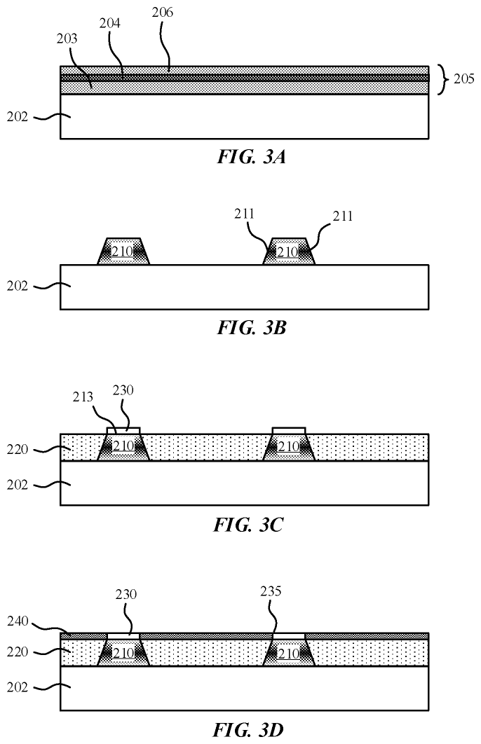

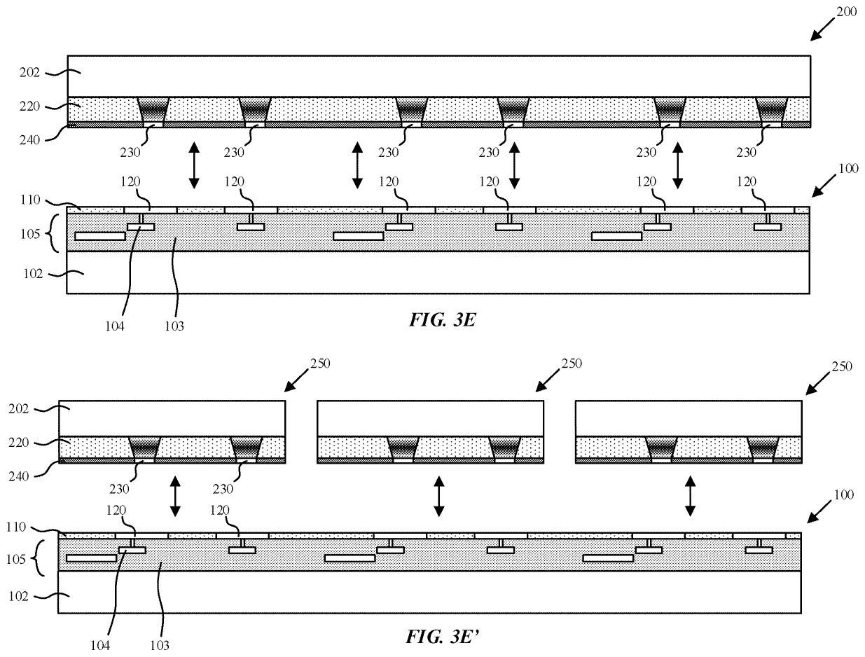

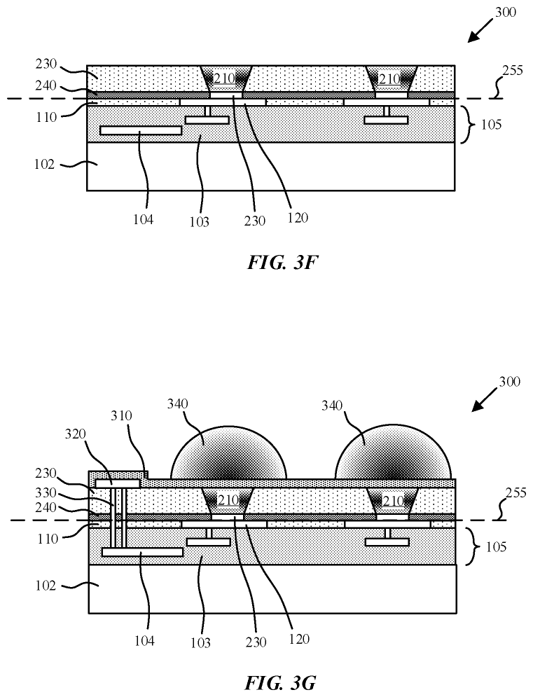

Additionally, FIGS. 3A-3G are schematic cross-sectional side view illustrations for a method of hybrid bonding in accordance with an embodiment. In interest of clarity and conciseness the process flows illustrated in FIGS. 1-2 are described with reference to common features shown in FIGS. 3A-3G. While the sequence illustrated in FIGS. 3A-3G specifically illustrates a hybrid bonding sequence for a plurality of micro LEDs and silicon driver substrate, it is to be appreciated that this implementation is exemplary, and the general hybrid bonding sequences described herein are applicable for a variety of wafer-to-wafer and die-to-wafer applications in the microelectronics industry.

Referring now to FIG. 1, a general hybrid bonding sequence 1000 in accordance with embodiments includes preparing a first substrate stack 100 at operation 1010 and second substrate stack 200 at operation 1020. As will become apparent in the following description, this may include applying an organic adhesive layer 240 to one of the substrate stacks, and optionally further processing the substrate stack with the organic adhesive layer to prepare the substrate stack for non-conductive bonding at room temperature. FIG. 2 includes operation 1010 sequence for preparing a substrate stack for non-conductive bonding in accordance with an embodiment. As shown, at operation 2010 an organic adhesive layer 240 can be applied over a dielectric layer 220 of the substrate stack (e.g. second substrate stack 200). The organic adhesive layer 240 can then be partially or fully cured at operation 2020, followed by optional polishing the organic adhesive layer 240, and optionally a plurality (or array) of conductive bonding regions 230 (e.g. copper bond pads) to form a planar bonding surface 235 at operation 2030. In an embodiment, the planar bonding surface 235 has an average surface roughness (Ra) of less than 0.5 nm.

The other corresponding substrate stack (e.g. first substrate stack 100) may separately be prepared for non-conductive bonding by forming a dielectric layer 110, such as SiCN, that will achieve a bonding surface energy with the organic adhesive layer 240 greater than 1.7 J/m2 after attaching the second substrate stack with the first substrate stack at room temperature.

Referring again to FIG. 1, at operation 1030 the first and second substrate stacks 100, 200 are brought together for non-conductive bonding at room temperature. In this instance, the organic adhesive layer 240 on one substrate stack (e.g. the second substrate stack 200) will bond to the dielectric layer 110 of the opposing substrate stack (e.g. the first substrate stack 100). At operation 1040 the substrate stack (e.g. the second substrate stack 200) including the organic adhesive layer 240 is thinned. For example, this thinning operation can include grinding, etching, laser lift off, etc. of a bulk substrate 202 (e.g. growth substrate) with different CTE than that of bulk substrate 102 of the opposing substrate stack. For example, CTE difference may be 2.0 or more, or even 3.0 or more. Once the bulk substrate with dissimilar CTE is removed, conductive bonding at elevated temperature can be performed at operation 1050 to bond/diffuse aligned conductive bonding regions 120, 230 (e.g. copper bond pads) of the opposing substrate stacks. Additional wafer or device processing and optional singulation can then be performed at operation 1060.

Referring now to FIGS. 3A-3G schematic cross-sectional side view illustrations are provided for a method of hybrid bonding in accordance with an embodiment. As shown the sequence can begin with FIG. 3A including a device layer 205 formed on a growth substrate 202. In an exemplary embodiment, the device layer 205 is a p-n diode layer including at a minimum a first doped layer 203 doped with a first dopant type (e.g. n-type), a second doped layer 206 doped with a second dopant type (e.g. p-type) opposite the first dopant type, and an active layer 204 between the first and second doped layers 203, 206. The active layer 204 may include one or more quantum well layers separated by barrier layers. In accordance with embodiments, the p-n diode layer 205 may be formed of III-V or II-VI inorganic semiconductor-based materials, and be designed for emission at a variety of primary wavelengths, such as red, green, blue, etc. The growth substrate may be chosen based on specific emission color, including sapphire or GaN for nitride-based LED (e.g. green, blue, UV emitting), or GaAs or GaP for phosphorous-based LEDs (e.g. red emitting).

The device layer 205 can then be patterned using a suitable technique such as dry and/or wet etching to form a plurality of diodes 210. The diodes 210 may be micro diodes, for example with a maximum lateral dimension of less than 100 microns, or more particularly less than 20 microns or less, such as less than 10 microns, less than 5 microns, or more specifically less than 3 microns. While only two diodes 210 are illustrated, a larger plurality or array of diodes 210 may be formed, for example, with a pitch of less than 20 microns. In an embodiment, the diodes 210 are separated by a pitch of less than 10 microns, with a density of greater than 90,000 per area of 3 mm×3 mm.

Following the formation of the diodes 210, one or more dielectric layers 220 may be formed around the diodes 210 as shown in FIG. 3C. While not separately illustrated, a variety of other optical features may be formed depending upon application, such as reflective structures around sidewalls 211 of the diodes 210. The dielectric layers 220 may provide passivation for the diodes 210 and/or step coverage for subsequent processing. Dielectric layers 220 may be deposited using suitable techniques such as chemical vapor deposition (CVD), or coated using techniques such as spray coating, spin coating, slot coating, etc. Suitable materials range from inorganic oxides, nitrides, etc. to organic polymers such as acrylic, benzocyclobutene (BCB), PBO, etc. The uppermost dielectric layer 220 and diodes 210 may optionally be polished/planarized. A plurality of conductive bonding regions 230 can then be formed on the exposed surfaces 213 of the diodes 210. Conductive bonding regions 230 may be single or multiple layer stacks. In an embodiment, conductive bonding regions include a top metal layer, such as copper, for bonding to (and interdiffusion with) a corresponding conductive bonding region 230 on an opposing substrate stack.

Referring now to FIG. 3D an organic adhesive layer 240 is applied over the dielectric layer 220 and the plurality of conductive bonding regions 230. For example, this can be achieved using spray coating, spin coating, or slot coating followed by curing to at least partially cross-link the organic adhesive layer 240. In accordance with embodiments, this may include a full cure or partial cure (e.g. B-staged) to retain tackiness. The organic adhesive layer 240 and conductive bonding regions 230 are then optionally polished back (e.g. with CMP) to achieve a planar bonding surface 235 for wafer bonding. The bonding surface 235 can also achieve preferred topography between the conductive bonding regions 230 (pads) and the organic adhesive layer 240. At this stage the second substrate stack 200 may optionally be diced into a plurality of dies 250 (see FIG. 3E′).

In accordance with embodiments, the dies 250 can have minimum lateral dimensions greater than 1 mm×1 mm, or more particularly greater than 3 mm×3 mm. In an embodiment, the diodes 210 are separated by a pitch of less than 10 microns, with a density of greater than 90,000 per area of 3 mm×3 mm. In particular, the hybrid bonding sequences described in accordance with embodiments can facilitate hybrid bonding of substrate stacks with dissimilar CTEs, enabling hybrid bonding of larger substrate to one another, including wafer-to-wafer hybrid bonding and die-to-wafer bonding with less stringent requirements on maximum die size to accommodate stresses due to CTE mismatch.

With the exemplary LED donor substrate stack 200 (i.e. second substrate stack) or dies 250 thereof now prepared, hybrid bonding may proceed with a backplane substrate stack 100 (i.e. first substrate stack) which has also been prepared to include a dielectric layer 110 for non-conductive room temperature bonding as shown in FIGS. 3E-3E′. In particular, FIG. 3E illustrates wafer-to-wafer bonding, while FIG. 3E′ illustrates die-to-wafer bonding. As shown, the first substrate stack 100 can include a first bulk substrate 102, and a routing layer 105 including a first dielectric layer 105 and a first plurality of first conductive bonding regions 120 over the first bulk substrate 102. More specifically, the bulk substrate 102 may be a silicon substrate with optional top epitaxial layer in which multiple devices (e.g. transistors, etc.) of driver circuitry are formed. The routing layer 105 may include many dielectric layers 103 and conductive (metal) routing 104 interconnect lines and vias to electrically connect the devices of the bulk substrate with the first conductive bonding regions 120 (e.g. copper pads). Dielectric layer 110 may be the uppermost dielectric layer which has been processed for non-conductive bonding at room temperature.

As already described, the second substrate stack 200 can include a second bulk substrate 202 (e.g. growth substrate for diodes), and a second dielectric layer 220 and a second plurality of second conductive bonding regions 230 (e.g. copper pads) over the second bulk substrate 202. The first and second substrate stacks are then attached with one another while aligning the second plurality of conductive bonding regions 230 with the first plurality of conductive bonding regions 120 to effect non-conductive bonding at room temperature using the organic adhesive layer 240.

The second bulk substrate 202 may then be removed as shown in FIG. 3F using suitable techniques such as grinding and polishing. During this sequence the bonding energy between the organic adhesive layer 240 and the first dielectric layer 110 may be greater than 1.7 J/m2 to provide sufficient adhesion to withstand removal of the second bulk substrate 202, which has mismatched CTE from the first bulk substrate 102. After removal of the second bulk substrate 202, the attached substrate stacks can be heated at elevated temperature to deform the first and second conductive bonding regions 120, 230 (e.g. cause interdiffusion) and form final bonded joints, which additionally have improved adhesion and electrical characteristics, and form the hybrid bonded structure 300. In an embodiment, the attached substrate stacks are heated to a temperature greater than 150° C., or even greater than 200° C. to achieve conductive bonding.

In accordance with embodiments, a bonding interface 255 exists between the hybrid bonded first substrate stack 100 and the second substate stack 200, with the bonding interface 255 extending between (or defined by contact of) the first dielectric layer 110 and the intermediate organic adhesive layer 240 and between the first plurality of first conductive bonding regions 120 and the second plurality of second conductive bonding regions 230.

Following completion of hybrid bonding, the hybrid bonded structure 300 can be further processed, for example using wafer level processing, depending upon application. In the embodiment illustrated in FIG. 3G, vertical interconnects 330 (e.g. copper vias) are formed through the stacked structure to contact conductive (metal) routing 104. This may be followed by formation of optional contact pad 320 and a transparent or semi-transparent top electrode layer 310 to electrically connect the top sides of the diodes 210 with the conductive routing 104. Additional structures may also be formed such as micro lenses 340. In the particular embodiment illustrated, a half-ball structure is illustrated, where refractive index can be selected for a desired emission profile, however embodiments are not limited to this particular application. Following the wafer level processing the hybrid bonded structure 300 can optionally be singulated into a plurality of separate dies. In an embodiment, the plurality of micro diodes 210 within the diced hybrid bonded structure 300 is dispersed across an area greater than 1 mm×1 mm, or more particularly greater than 3 mm by 3 mm, whether or not the second substrate stack 200 was previously diced into dies 250 prior to hybrid bonding.

In utilizing the various aspects of the embodiments, it would become apparent to one skilled in the art that combinations or variations of the above embodiments are possible for fine pitch hybrid bonding with dissimilar CTE substrates. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A method of hybrid bonding comprising:
attaching a second substrate stack with a first substrate stack with an organic adhesive layer located on either the first substrate stack or the second substrate stack;
wherein:
the first substrate stack comprises a first bulk substrate, and a first dielectric layer and a first plurality of first conductive bonding regions over the first bulk substrate;
the second substrate stack comprises a second bulk substrate, and a second dielectric layer and a second plurality of second conductive bonding regions over the second bulk substrate; and
attaching the second substrate stack with the first substrate stack comprises aligning the second plurality of conductive bonding regions with the first plurality of conductive bonding regions;
removing the second bulk substrate; and
heating the attached first and second substrate stacks after removing the second bulk substrate to diffuse the second plurality of conductive bonding regions with the first plurality of conductive bonding regions.

2. The method of hybrid bonding of claim 1, further comprising:
applying the organic adhesive layer over the second dielectric layer and the second plurality of second conductive bonding regions; and
at least partially curing the organic adhesive layer prior to attaching the first substrate stack with the second substrate stack.

3. The method of claim 2, further comprising polishing the organic adhesive layer and the second plurality of conductive bonding regions to form a planar bonding surface.

4. The method of claim 3, wherein the planar bonding surface has an average surface roughness (Ra) of less than 0.5 nm.

5. The method of claim 2, wherein the attaching the second substrate stack with the first substrate stack is performed at room temperature.

6. The method of claim 5, wherein the organic adhesive layer has a bonding surface energy with the first dielectric layer greater than 1.7 J/m2 after attaching the second substrate stack with the first substrate stack is performed at room temperature.

7. The method of claim 6, wherein the first dielectric layer comprises SiCN.

8. The method of claim 6, wherein heating the attached first and second substrate stacks to diffuse the second plurality of conductive bonding regions with the first plurality of conductive bonding regions is performed at a temperature greater than 150° C.

9. The method of claim 6, further comprising dicing the attached first and second substrate stacks into a plurality of dies after diffusing the second plurality of conductive bonding regions with the first plurality of conductive bonding regions.
